(19) United States
(12) Patent Application Publication
(10) Pub. No.: US 2012/0179397 A1
(43) Pub. Date: Jul. 12, 2012

(54) UTILITY MONITORING SYSTEM

(76) Inventors: James Allen Buslepp, Livonia, MI (US); John Gerard Finch, Livonia, MI (US)

(21) Appl. No.: 13/344,886

(22) Filed: Jan. 6, 2012

Related U.S. Application Data
(60) Provisional application No. 61/430,638, filed on Jan. 7, 2011.

(51) Int. Cl. G06F 19/00; G01R 21/00; G01R 19/00

(52) U.S. Cl. 702/62; 702/64

(57) ABSTRACT

A method of monitoring utility usage receives utility usage data from at least one local utility sensor and uses a local server to determine a utility usage for a selected time period based on the utility usage data. The local server is also used to determine a current utility usage rate. A utility usage display illustrating at least a portion of the utility usage data is transmitted to a web browser or client application of at least one computing device. The utility usage display includes a ticker indicating the determined utility usage and the current utility usage rate. The ticker includes a rotating dial rotating at a rotational speed proportional to the current utility usage rate. The display also includes a usage scale illustrating a difference between the determined utility usage and one or more desired utility usage goals.

### RELATED APPLICATION

This application claims priority to U.S. Provisional Application No. 61/430,638, filed Jan. 7, 2011.

### BACKGROUND OF THE INVENTION

This disclosure relates to utility monitoring, and more particularly to a utility monitoring system providing an electronic display of utility usage.

Although home occupants may wish to reduce an amount of money spent on monthly utility bills, tracking utility usage throughout a month can be difficult, as the immediate impact of daily utility usage decisions is often unclear. Therefore, home utility conservation efforts are difficult to quantify, making it difficult for home occupants to determine the benefit of such efforts.

### SUMMARY

A method of monitoring utility usage receives utility usage data from at least one local utility sensor and uses a local server to determine a utility usage for a selected time period based on the utility usage data. The local server is also used to determine a current utility usage rate. A utility usage display illustrating at least a portion of the utility usage data is transmitted to a web browser or client application of at least one computing device. The utility usage display includes a ticker indicating the determined utility usage and the current utility usage rate. The ticker includes a rotating dial rotating at a rotational speed proportional to the current utility usage rate. The display also includes a usage scale illustrating a difference between the utility usage and one or more desired utility usage goals.

A utility monitoring system having a local server having a wireless receiver, at least one remote monitor having a sensor module, the sensor module having a plurality of Current Transformer (CT) sensors for sensing electric power entering a junction box, a sensor module housing mounted outside the junction box and hard wired to the plurality of CT sensors, wherein each of the CT sensors is mounted within the junction box, and the sensor module housing having at least a general sensor module controller, a wireless transmitter/receiver, and a status indicator.

These and other features of the present invention can be best understood from the following specification and drawings, the following of which is a brief description.

### BRIEF DESCRIPTION OF THE DRAWINGS

FIG. 1 schematically illustrates an example home utility monitoring system.

FIG. 2 illustrates a household junction box including a sensor module.

FIG. 3 illustrates a sensor module housing.

FIG. 4 schematically illustrates a main utility usage view for a plurality of utilities.

FIG. 5 schematically illustrates a detailed view of electricity usage.

FIG. 6 schematically illustrates a detailed view of solar production.

FIG. 7 schematically illustrates a detailed view of water usage.

FIG. 8 schematically illustrates a detailed view of gas usage.

FIG. 9 schematically illustrates a configuration view where utility goals can be defined, and utility rates can be adjusted.

### DETAILED DESCRIPTION

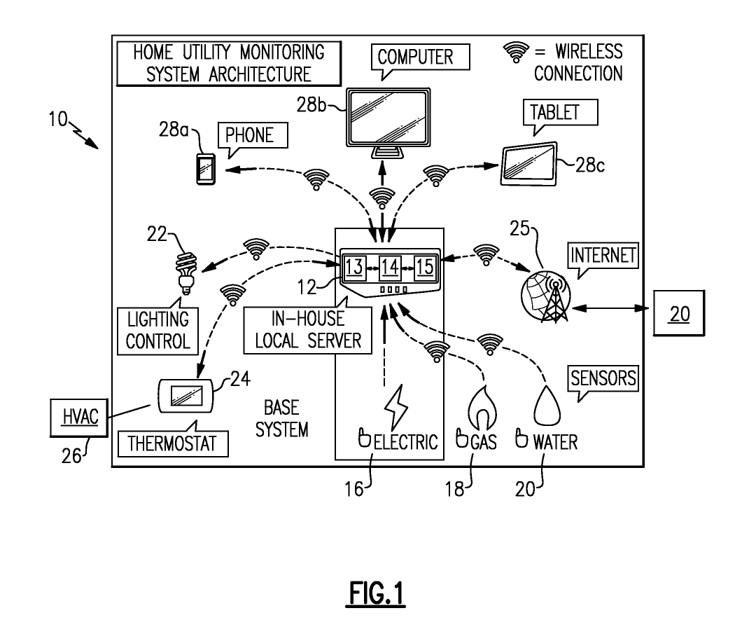

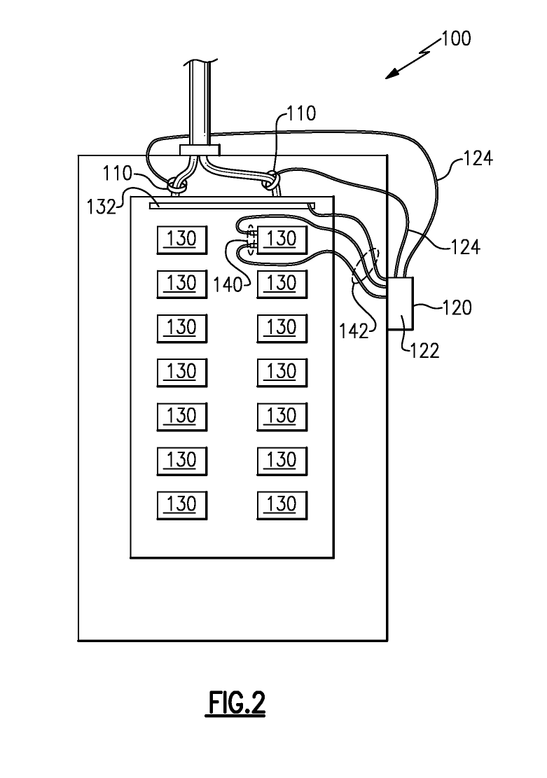

FIG. 1 schematically illustrates an example home utility monitoring system 10 in which a local server 12 analyzes utility usage data and provides utility monitoring and usage data to a plurality of computing devices 28a-c.

The local server 12 includes an input/output (I/O) device 13, a microprocessor 14, and at least one storage device 15. The storage device 15 includes memory, hard drives, or any other electronic, optical, magnetic or other type of computer storage. As shown in FIG. 1, The local server 12 is in communication with multiple components through the I/O device 13. The I/O device 13 is operable to communicate over a wired or wireless connection with a plurality of components (e.g. computing devices 28a-c).

The system 10 includes at least one utility sensor, such as an electricity sensor module 16, gas sensor 18, or water sensor 20. Although the illustrated system 10 can operate with only a single sensor sensing a single utility, the system 10 is scalable and can include sensors for multiple varied utilities, and can include multiple varied sensors for a single utility. Each of the sensor modules 16, 18, 20 is operable to provide utility usage data to the local server 12 for its respective utility.

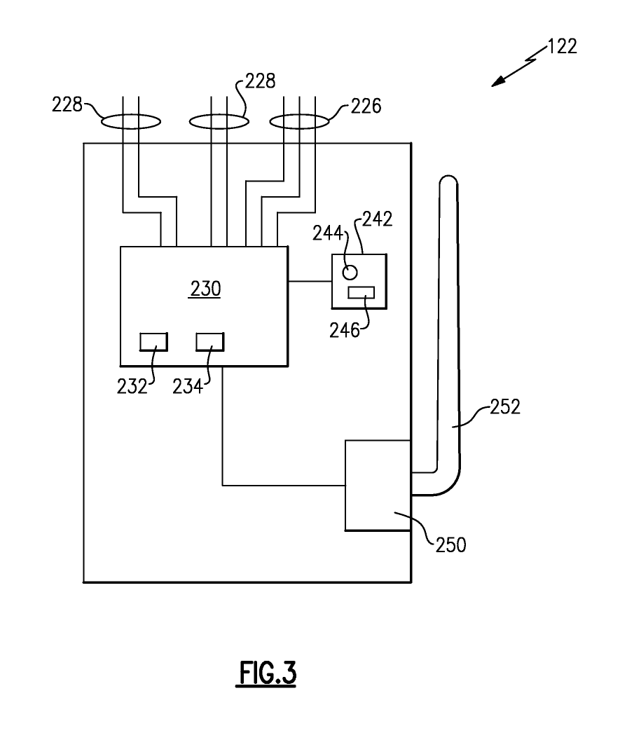

In one example the electric sensor module 16 is placed inside a home electric service panel (illustrated in FIG. 2) and communicates with the local server 12 using power line communication. In another example the gas sensor 18, water sensor 20, or both communicate with the local server 12 using a radio (e.g., a ZigBee radio or an Enocean radio), or communicate with the local server 12 using Wi-Fi. The local server 12 receives utility usage data from the sensor modules 16, 18, 20 and, as will be discussed below, is able to provide a variety of utility monitoring features in response to the utility usage data.

The local server 12 is in communication with at least one computing device 28a-c having a web browser or client application that may be used to display utility usage data from the local server 12. Some example computing devices include a mobile phone 28a, desktop computer 28b, or touch-based tablet computer 28c. Of course, these are only examples, and it is understood that other computing devices having web browsers or other client applications could be used. In one example, the computing devices 28a-c merely display graphical data transmitted from the local server 12 illustrating utility usage, and the computing devices 28a-c do not actually process any utility usage data received from the sensors 16, 18, 20. In this example, all processing of the utility usage data from the sensors 16, 18, 20 is performed by the local server 12.

The local server 12 is also in communication with a wide-area network 25 (e.g. the Internet), and may download information from or store content on remote server 30. For example, the local server 12 may download utility rate information from remote server 30, or may download software updates from remote server 30. The remote server may also provide remote access to the system 10 from outside an associated structure of the system 10 (e.g. a home).

The system 10 is scalable, in that multiple copies of sensors can be included, and the local server 12 can reconcile the data from those multiple sensors. This may be desirable from a redundancy standpoint (e.g. include multiple water sensors 20 in case one fails), or for larger structures (e.g. if a building includes multiple water mains, then multiple sensors may be desirable). Additional settings may also be used to disaggregate data. For example separate water sensors 20 might be put on hot and cold water pipes to monitor the use of each separately in addition to monitoring combined usage.

Additionally, the system 10 is scalable in that multiple energy harvesting sources can be added to the system at a later date and added in the configuration view 80. For example, if a wind turbine generator, geothermal generator, or additional photovoltaic solar cells were added to the system 10, then these sources could be included or excluded in the configuration view 80 using, for example, a checkbox similar to checkbox 88.

FIG. 2 illustrates a household junction box 100 including two current transformer (CT) sensors 110. The CT sensors 110 are part of a sensor module 120, with the remaining sensor module components contained within a sensor module housing 122. Each CT 110 is connected to the sensor module housing 122 via a two wire connection 124, with each two wire connection 124 illustrated as a single connection line in FIG. 2. In addition to the CT connection, a voltage tap 140 taps into power lines connected on the load side of each pole of a two pole breaker 130 and a neutral bar (132), and is connected to the sensor module 120 via a three wire connection 142. The three wire connection 142 includes two hot wires (phase A and phase C) as well as a neutral wire.

Each of the CTs 110 include a current sensor that detects the current entering the junction box 100. The two wire connection 124 connecting the CT sensor 110 to the sensor module 120 housing carries current sensor information that the sensor module 120 can interpret and transmit to the local server 12. Likewise, the three wire connection 142 from the voltage tap 140 carries voltage sensor information that the sensor module 120 can interpret and transmit to the local server 12.

FIG. 3 illustrates the sensor module housing 122 in greater detail. The housing includes one input 226 operable to accept the three wire connection 142 (illustrated in FIG. 2). The input 226 feeds into a general module controller 230 that includes a processor 232 and a memory 234, such that the general module controller 230 can interpret the received sensor information from the voltage tap 140 within the junction box. Likewise, the housing includes two inputs 228, each operable to accept one of the two wire connections 124. The inputs 228 feed into the general module controller 230, thereby allowing the general module controller 230 to interpret the received sensor information from the CT sensors 110. A status indicator 242 is connected to the general sensor module controller 230 and includes an LED 244 that indicates when the sensor module 122 is functioning. The status indicator 242 also includes a reset switch 246 that can be used to reset the sensor module 122. The general sensor module 122 also receives operational power from the three wire connection 142 and the voltage tap 140.

A radio transmitter/receiver 250 is connected to the general module controller 230 and is operable to transmit interpreted sensor readings from the general module controller 230 to the local server 12. In an alternate embodiment, the transmitter/receiver 250 transmits raw sensor readings that are then interpreted by the local server 12. An antenna 252, mounted to the side of the sensor module housing 122, facilitates the transmission and receipt of communications between the sensor module 122 and the local server 12. Alternatively, the antenna 252 can be mounted inside the sensor module housing 122 or printed on a printed circuit board within the sensor module housing 122. The communications can be in a standard form, or alternately, can be encrypted by the general sensor module controller 230.

While the sensor module 122 illustrated in FIGS. 2 and 3 includes two CT sensors 110 and a voltage tap 140, additional CT sensors and voltage taps within a single junction box 100, or in multiple adjacent junction boxes, could be added to increase the sensing capability. Furthermore, while the two illustrated CT sensors 110 and the voltage tap 140 are illustrated reading the power flow across main lines into the junction box 100, it is alternately possible to place a CT and/or voltage tap on a single junction 130 and thereby sense the electricity being utilized by a single circuit. This alternate configuration can allow the local server 12 to determine exactly how much power is being utilized by certain large appliances that operate on their own circuit.

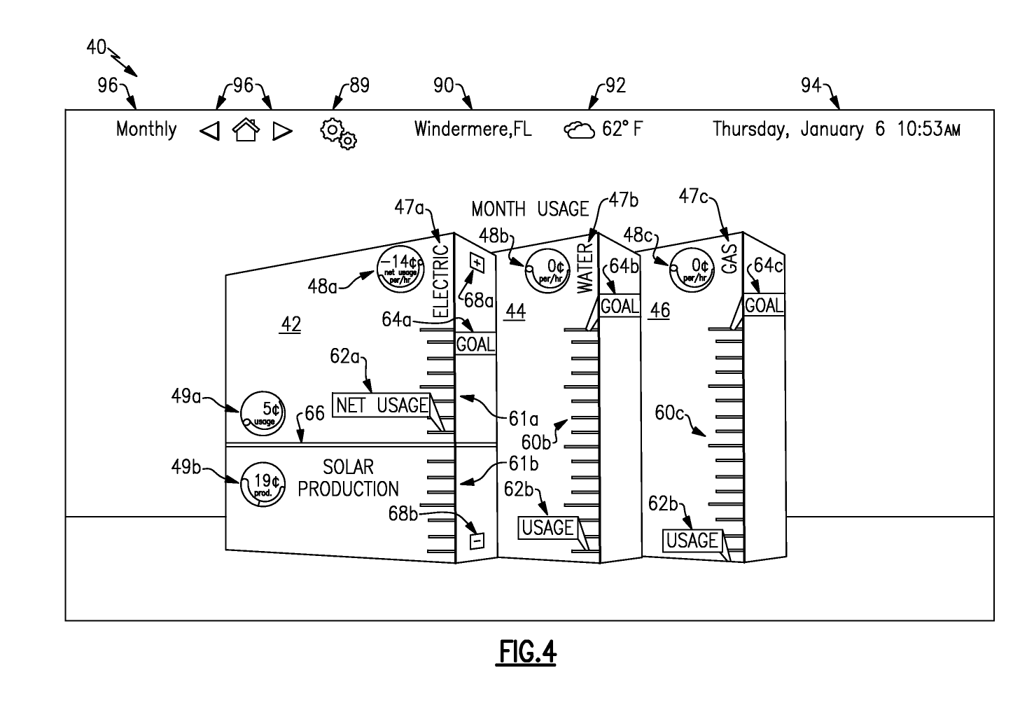

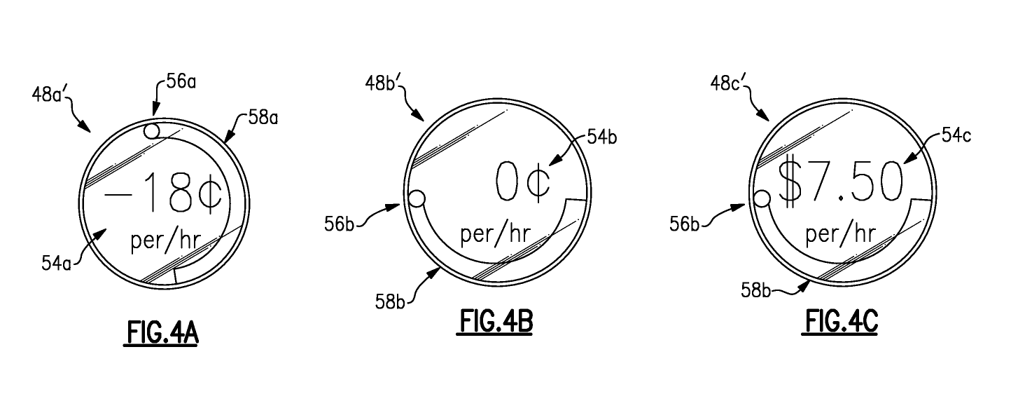

FIGS. 4-9 schematically illustrate utility monitoring views produced by the local server 12 and accessible on a web browser or client application of the computing devices 28a-c. Referring to FIG. 4, a main view 40 illustrates usage data for an electric utility 42 (including both consumption and solar energy production data), a water utility 44, and a gas utility 46 for a selected time period (e.g., a month in the example of FIG. 4). Although a monthly usage view is shown, it is understood that other views would be possible (e.g., daily, weekly, yearly, etc.).

As shown in FIG. 4, each utility 42-46 may be illustrated as a rotatable book, with each utility including a label 47a-c and a background image indicating its utility type. For example, the book for the electric utility 42 may include a background image of yellow rays of light for solar production and may include a background image that is green for electric usage, the book for the water utility 44 may include a background image of blue water, and the book for the gas utility 46 may include a background image of red gaseous material. Alternate images and colors could be used. Although the utilities 42-46 are arranged in a particular order in the example of FIG. 40, it is understood that this is only an example, and a user can rearrange the utilities 42-46. Also, it is understood that some of the utilities 42-46 may be omitted from the view 40 if there was no corresponding sensor present for the utility.

The view 40 includes an associated ticker 48 for each utility, with electric utility 42 having associated ticker 48a, water utility 44 having associated ticker 48b, and gas utility 46 having associated ticker 48c. The tickers are shown in greater detail in FIGS. 4a-c (with the tickers 48a′, 48b′ and 48c′ of FIGS. 4a-c using different example values than their corresponding tickers 48a-c of FIG. 4). Each ticker 48a′, 48b′, 48c′ indicates a utility usage rate using both a text indicator 54a-c and a rotating dial 56a-c. In one example the rotating dial rotates at a rotational speed proportional to the usage rate (e.g. dial 54c would rotate at a faster rate at $7.50 per/hr than at $5.00 per/hr).

A direction of rotation of the rotating dial 56 may be used to indicate net utility usage or net utility production. For example, in the ticker 48a′ the usage rate is −$0.18 per/hr indicating that more electricity is being produced than consumed (e.g. via usage of solar panels on a home). As indicated by dial trail 58a of ticker 48a′, the dial 56a is rotating counter-clockwise to indicate net utility production, whereas the dials 56b-c as indicated by dial trails 58b-c are rotating clockwise to indicate net utility consumption. Referring again to FIG. 4, for the ticker 48a which is indicating a net utility production, additional tickers 49a-b may be provided to indicate the separate usage and production rates for the electric utility 42.

The display for each utility 42-46 also includes a relative usage scale 60 comparing utility usage tab 62 to a utility goal tab 64. The scale 60 is relative in that numbers for the scale may be omitted to illustrate proximity between usage (see usage tab 62) and a usage goal (see goal tab 64) for the selected time period instead of using actual numeric usage values. For example, in the book display for gas utility 46 the usage tab 62c is close to or at zero for the selected monthly time period, indicating a negligible amount of gas usage for the time period. However, in the book display for gas utility 44, the usage tab 62b is at approximately the 10% mark as compared to goal tab 64bc, indicating that approximately 10% of a desired monthly water usage has already occurred.

In one example, if a usage tab 62 surpassed a goal tab 64, the relative scale 60 could simply recalibrate to place usage tab 62 at the top of scale 60 and proportionally move the goal tab 64 below the usage tab.

Referring to the display for the electric utility 42, because both usage and consumption are illustrated, the scale 60a may be separated into a positive portion 61a to illustrate consumption and a negative portion 61b to illustrate production, with the portions 61a-b being separated by a net zero point indicator 66. The net zero point indicator 66 may be adjusted by clicking on “+” or “−” buttons 68a-b, for example.

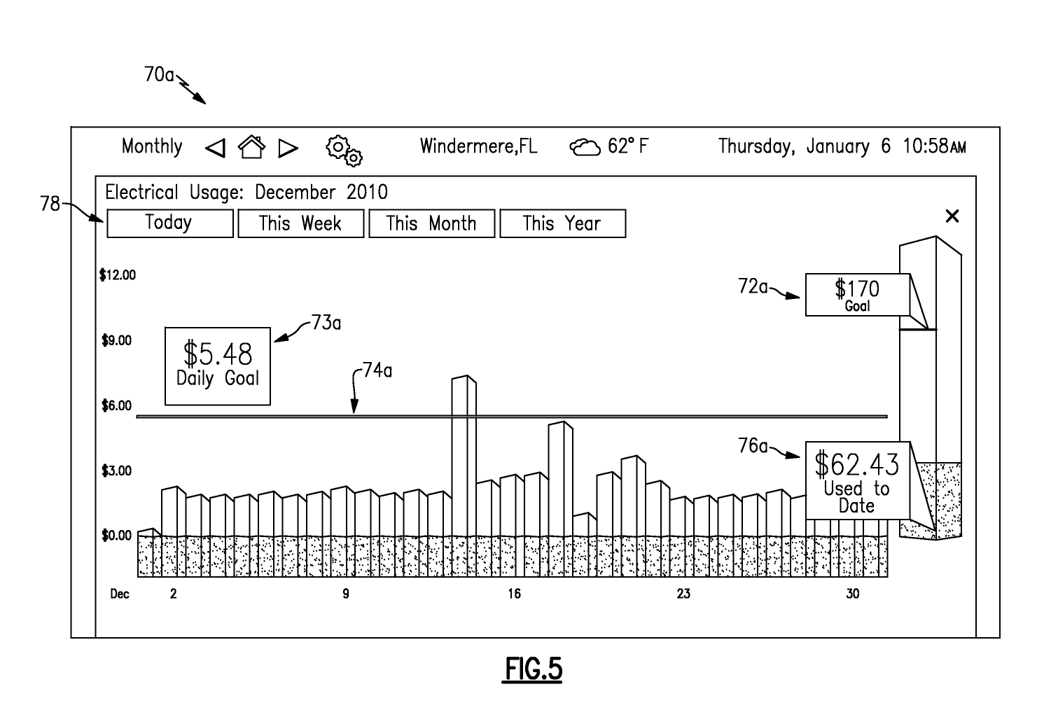

In addition to the main view 40 described above, more detailed views 70a-c of specific utilities are available in the system 10 (see FIGS. 5-8). In one example if a user selects one of the books for utilities 42, 44, 46 they will enter one of the detailed views 70a-c shown in FIGS. 3-6.

Referring to FIG. 5, the view 70a illustrates detailed electrical usage information for a selected time period. Although a “December 2010” time period is selected in FIG. 5, it is understood that other time periods may be selected (e.g., “Today,” “This Week,” “This Year”). For example, different time periods may be selected using time period button 78, or backward/forwards buttons 98 (see FIG. 4).

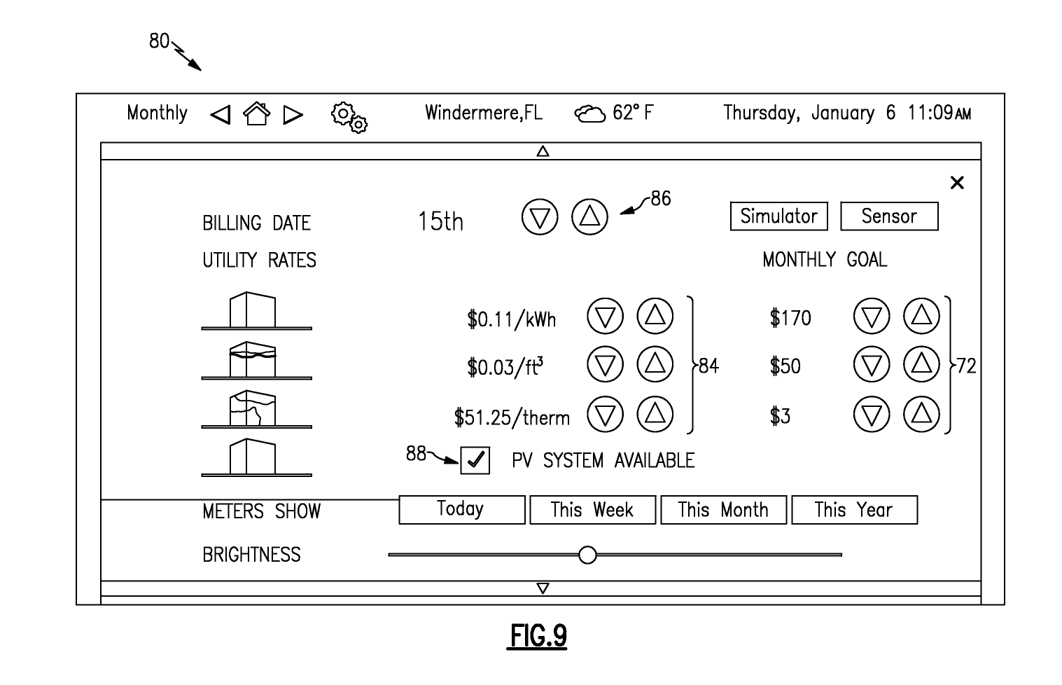

As shown in the electrical usage view 70a, a monthly goal of $170 for electrical utility usage is divided by a 31 days in the month of December, to reach a daily goal 73a of $5.48, also shown by line 74a. The daily usage 73a and usage to date 76a values are determined based on data received from the sensors 16-20 and based on utility rate information (described below in connection with FIG. 9). The view 70a shows how utility usage for each day of the selected month of December 2010 compares to the daily goal of $5.48, and also shows a monthly usage to date value 76a of $62.43. Unlike the view 40 of FIG. 4 which was only relative, the view 70 includes numeric values.

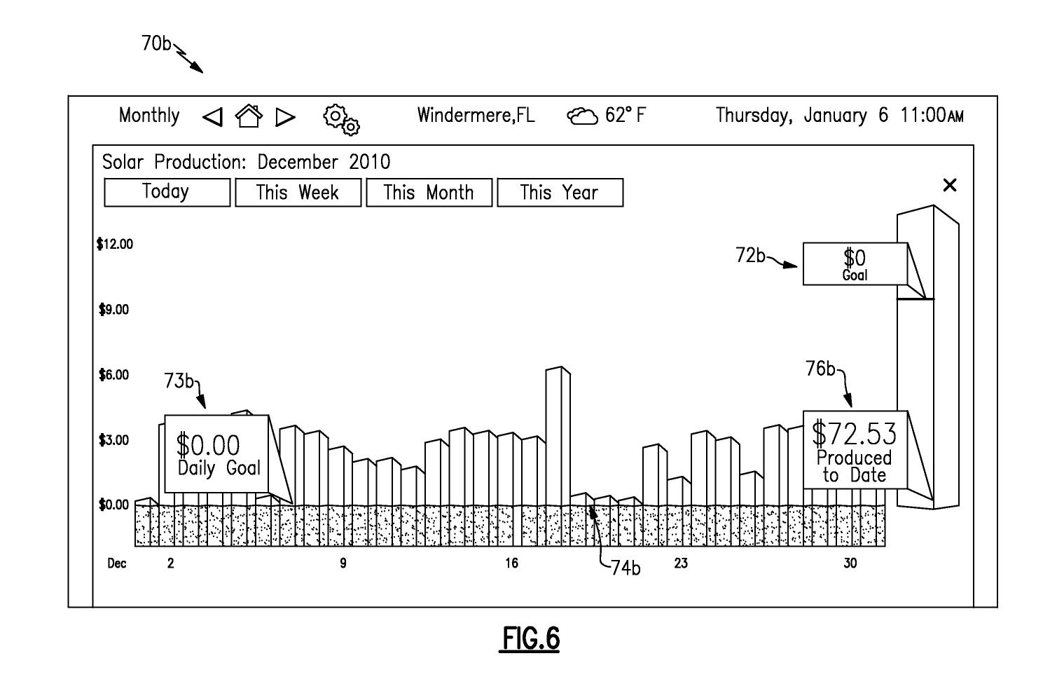

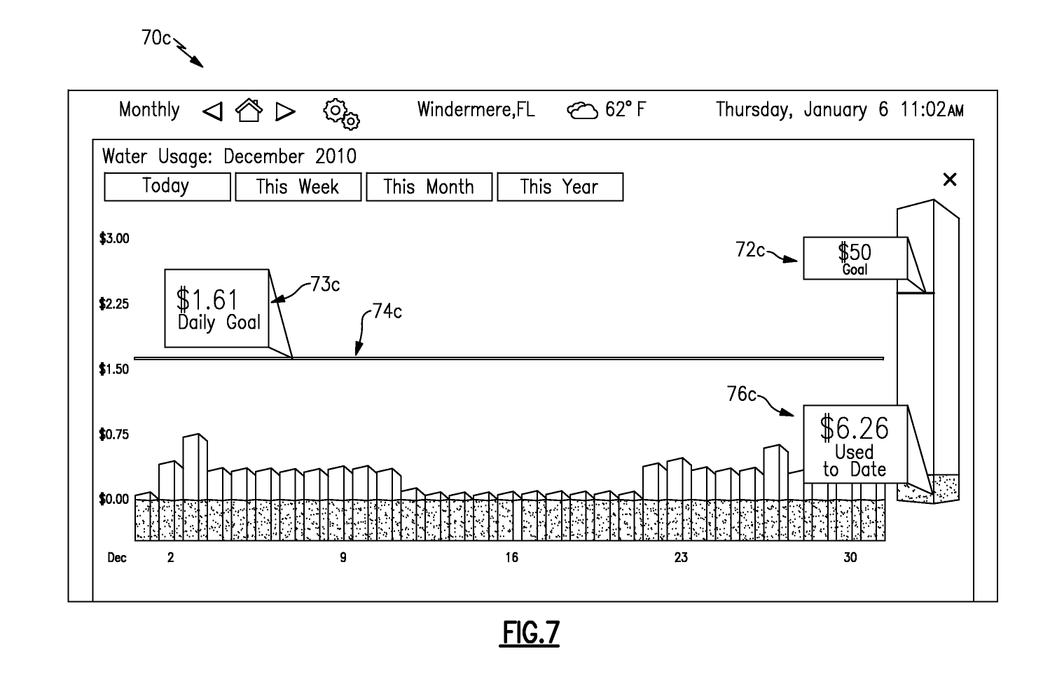

The solar production view 70b of FIG. 6 includes a monthly goal 72b of $0, and a daily goal 73b of $0 (indicated by line 74b). However, instead of illustrating an amount used to date 76a of $62.43, the view 70b illustrates an amount produced to date 76b of $72.53 (reflecting net electrical energy being produced by the building associated with the system 10). Thus, the goal 72b in view 70b is a production goal instead of a usage goal. Referring to FIG. 7, a water usage view 70c illustrates a monthly view of water usage, including a monthly goal 72c of $50, a daily goal 73c of $1.61 (also indicated by line 74c), and a usage to date 76c of $3.80.

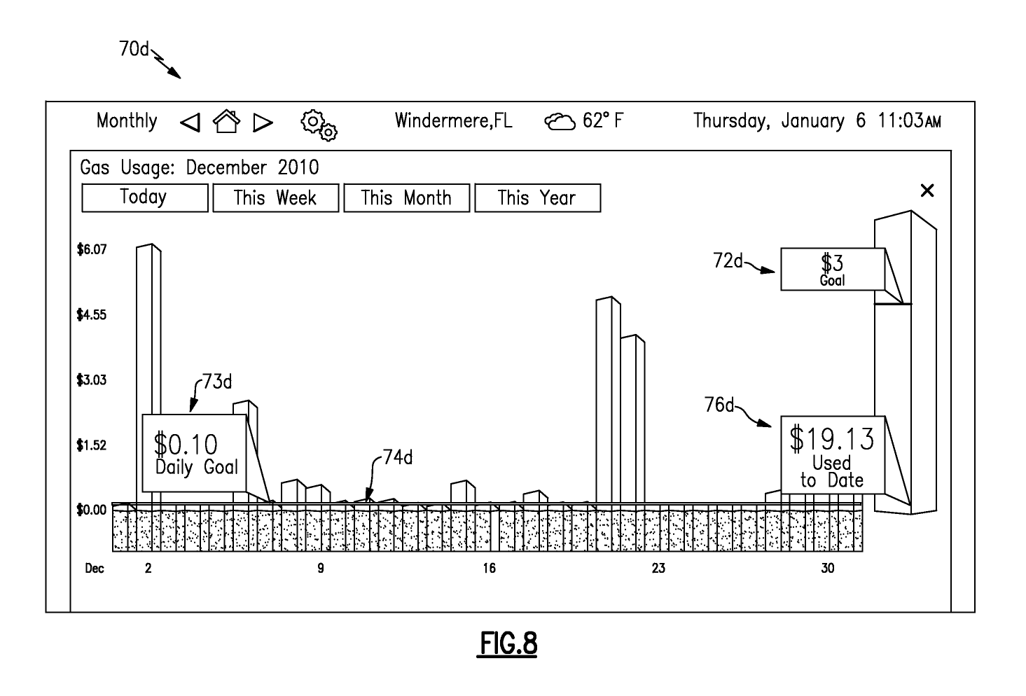

Referring to FIG. 8, a gas usage view 70d illustrates a monthly view of gas usage, including a monthly goal 72c of $3, a daily goal 73d of $0.10 (also indicated by line 74d), and a usage to date 76d of $19.13. The goals 72 will now be described in greater detail. In the system 10, goals give users useful, actionable information about their utility usage. Instead of merely reading a utility bill at the end of a month, a user is able to see how their daily decisions affect utility usage. For example, a user could simply turn a selected appliance ON to see how that appliance affects their current electrical usage rate (shown in ticker 48a).

In one example, the system 10 is operable to provide alerts if a threshold has been reached. For example, if a user has exceeded their daily goal for a predefined quantity of days, an alert may be provided to the user (e.g., visual or auditory warning, or an email alert).

The system 10 is operable to conveniently convert utility rate information into easily understandable units. For example, gas is typically measured in thousands of cubic feet (MCF) and water is typically measured in hundreds of cubic feet (CCF). Instead of telling a user how many MCF of gas or CCF of water have been used, the system 10 may tell them how many dollars per hour they have consumed using utility rate information accessible by the local server 12. Of course, these are only examples, and it is understood that other easily understood units such as kilowatts, gallons or cubic feet may be optionally used in response to user preferences.

The system 10 includes autoscaling features for the view 40, 70 to appropriately place the tabs 62, 64 (see FIG. 4) and daily utility usage line 74 (see FIGS. 5-8) at appropriate positions to avoid, for example, the tabs 62, 64 or usage 74 extending beyond a visible screen area, or to avoid the line 74 being so close to zero that that one cannot decipher meaningful data from the line 74.

FIG. 9 schematically illustrates a configuration view 80 in which utility goals 72 can be set, and utility rates 84 and a billing date 86 can be adjusted. For example, if a user determined that their goals were too high or too low, the user could be used to adjust those goals by clicking the corresponding increase or decrease buttons next to the goals. The billing date 86 may be used to indicate a date at which the user receives bills for a selected utility. Although not shown in FIG. 8, a user may be able to customize additional settings, such as the background images of book of utilities 42, 44, 46, the colors assigned to the various utilities, etc.

In one example the configuration view 80 is accessed using the settings button 89 (see, e.g., FIG. 4). In one example the utility rates 84 are user-entered. In one example the utility rates 84 are downloaded from a utility service provider (e.g., via remote server 30). If desired a user may also customize an axis of the views 40, 70. For example, instead of viewing dollars per day (see FIG. 5) or dollars per hour (see FIG. 4), a user may want to view usage in terms of other non-currency units (e.g. cubic feet of water or gas).

Referring again to FIG. 9, using checkbox 88, energy harvesting devices (e.g. photovoltaic solar cells) may be selected or deselected for inclusion or exclusion from the views 40, 70 of the system. Due to the user-friendly nature of the system 10, these configurations can easily be performed by end-user building residents, instead of relying on technicians.

The local server 12 stores historical utility usage data in its storage device 15. This data only requires a small amount of memory, as once a base time period is saved (e.g. utility usage by hour) additional time periods can simply be calculated as needed (e.g. calculate monthly usage using the stored daily usages). The local server 12 can alternately store the computed usage data for those computed larger time periods (e.g., week, month, year, etc.). In one example, a user may select past and subsequent time periods by using buttons 98 in view 40 (see FIG. 4).

The system 10 also includes various localization features. Referring to FIG. 4, the view 40 displays a user residence city 90. In one example this city may be determined by a user entering a zip code or a city name. In response to the city 90, weather data 92 may be provided. Date and time information 94 may also be displayed. Based upon the user residence city 90, a time zone may be automatically determined for the date and time information 94. Also, based on the user residence city 90, units may be localized. For example, the system 10 may choose to whether or not to use metric units, or may choose an appropriate currency for the tickers 48a-c based on the user residence city 90.

Existing utility monitoring systems obtain utility usage information from utility companies, which introduces a significant lag time. The lag time causes a negative user experience, as a user is unable to determine the short term impact of their utility usage actions (e.g. “how much electricity is used when I turn an appliance ON?”). Because all utility usage data is obtained locally using sensor modules 16, 18, 20 the usage information for views 40, 70 can be provided much quicker to provide real-time utility usage data.

The system 10 provides a convenient, visually engaging, unified interface in the form of view 40 so that a user can view a quick summary of relevant utility monitoring information with additional details being readily accessible in the detailed views (e.g. views 70a-d). However, a user can obtain a majority of relevant information at a glance by simply relying on view 40.

Additionally, the local server 12 also provides users with a convenient way to control home utilities. As shown in FIG. 4, the local server 12 is operable to communicate with lighting control system 22 to control various lighting loads in an associated structure (e.g. a home), and the local server 12 is operable to communicate with thermostat 24 to control HVAC system 26 for the associated structure. Thus, a user could connect to the local server 12 from the web browser or client application of their computing device 28 to change a household utility mode (e.g., enter vacation mode, enact lighting scene, reduce temperature of water heater, etc.) with the mode affecting lighting control system 22 or HVAC system 26.

Although multiple examples have been disclosed, a worker of ordinary skill in this art would recognize that certain modifications would come within the scope of this disclosure. For that reason, the following claims should be studied to determine the true scope and content of this invention.

What is claimed is:

1. A method of monitoring utility usage, comprising:
receiving utility usage data from at least one local utility sensor;
determining a utility usage for a selected time period based on the utility usage data, wherein the utility usage is determined using a local server;
determining using the local server a current utility usage rate; and
transmitting a utility usage display illustrating at least a portion of the utility usage data to a web browser or client application of at least one computing device.

2. The method of claim 1, wherein said step of determining using the local server a current utility usage rate comprises determining a local utility usage rate using only data derived from a local utility monitoring system.

3. The method of claim 1, wherein said step of transmitting a utility usage display further comprises encrypting said utility usage display such that only an authorized user may view said utility usage display.

4. The method of claim 1, wherein said utility usage display comprises displaying said current utility usage rate using one of a dollars per month, dollars per week, dollars per day, dollars per hour, dollars per minute, or dollars per second unit.

5. The method of claim 1, wherein said utility usage display further comprises a display of a utility usage rate for each of at least one CT current sensors.

6. The method of claim 1, wherein said step of transmitting a utility usage display illustrating at least a portion of the utility usage data to a web browser or client application of at least one computing device further comprises the utility usage display including an indicator indicating the determined utility usage and the current utility usage rate.

7. The method of claim 6, wherein said indicator further includes a rotating dial rotating at a rotational speed proportional to the current utility usage rate.

8. The method of claim 6, wherein said display includes a usage scale illustrating a difference between the determined utility usage and one or more desired utility usage goals.

9. A utility monitoring system comprising:
a local server having a wireless transmitter/receiver;
at least one remote monitor comprising a sensor module;
said sensor module supporting one or more Current Transformer (CT) sensors for sensing electric current entering a junction box, one or more voltage connections operable to measure source voltage in a junction box, a sensor module housing mounted outside said junction box and hard wired to said one or more CT sensors and hard wired to said voltage sensing connections, wherein each of said CT sensors and said voltage sensing connections are mounted within said junction box; and
said sensor module housing having at least a general sensor module controller, a wireless transmitter/receiver.

10. The utility monitoring system of claim 9, wherein one or more CT sensor wire outputs are operable to transmit sensed current information from said one or more CT sensors to said general sensor module controller.

11. The utility monitoring system of claim 9, wherein voltage sensor connections connecting said one or more voltage connection to said general sensor module controller are operable to transmit sensed voltage information to said general sensor module controller.

12. The utility monitoring system of claim 9, wherein at least one CT sensor wire outputs is operable to transmit operational power to said sensor module from a power tap in said junction box.

13. The utility monitoring system of claim 9, wherein said remote sensor module further comprises a wireless transmitter/receiver operable to facilitate communication between said remote sensor module and said local server.

14. The utility monitoring system of claim 9, wherein at least one of said CT current sensors is connected to a single electrical circuit, such that said at least one CT current sensor detects electrical power used by said single electrical circuit.

15. The utility monitoring system of claim 9, wherein said general sensor module controller is operable to encrypt sensed sensor data prior to transmitting said sensor data to said local server.

16. The utility monitoring system of claim 9, wherein said remote sensor module further comprises a status indicator having an LED and a reset switch, wherein said LED indicates the operational status of said remote sensor module and said reset switch is operable to reset said remote sensor module.

17. The utility monitoring system of claim 9, wherein said remote sensor module is scalable such that a varied number of CT sensors can be connected to said remote sensor module.
